(19) United States
(12) Patent Application Publication
(10) Pub. No.: US 2003/0203511 A1
(43) Pub. Date: Oct. 30, 2003

(54) Method of manufacture of ferroelectric memory

(76) Inventor: Kinya Ashikaga, Tokyo (JP)

Correspondence Address: VOLENTINE FRANCOS, PLLC, Suite 150, 12200 Sunrise Vally Drive, Reston, VA, 20191, US

(21) Appl. No.: 10/307,411

(22) Filed: Dec. 2, 2002

(30) Foreign Application Priority Data
Apr. 26, 2002 (JP) 126116/2002

(51) Int. Cl. H01L 21/00

(52) U.S. Cl. 438/3

(57) ABSTRACT

For the purpose of converting ferroelectric memory between (use as) RAM and ROM, a method of manufacturing a read-only memory (ROM) using a ferroelectric memory is realized by a chip assembly process to perform chip assembly for ferroelectric memory; a data writing process to write data to the ferroelectric memory after the chip assembly process; and a first heat treatment process to subject the ferroelectric film of ferroelectric memory, after the data writing process, to a heat treatment at a heat treatment temperature T1 (° C.) lower than the phase transition temperature T_{c} (° C.) of the ferroelectric film. Further, a second heat treatment process is conducted in a method of manufacturing RAM using ferroelectric memory which has been converted into ROM, for subjecting the ferroelectric film of ferroelectric memory, which has been converted into ROM through the above processes, to a second heat treatment process, entailing heating of the ferroelectric film at a heat treatment temperature T2 (° C.) equal to or higher than the phase transition temperature T_{c} (° C.) of the ferroelectric film.

### BACKGROUND OF THE INVENTION

1. Field of the Invention

This invention relates to a method of manufacture of nonvolatile memory, and in particular ROM (read-only memory), which uses ferroelectric memory, as well as to a method of manufacture of RAM (random-access memory) utilizing ferroelectric memory converted into ROM.

2. Description of Related Art

In recent years, ferroelectric memory (Fe RAM: ferroelectric RAM) has attracted attention as a type of nonvolatile memory.

Ferroelectric memory is memory formed using a ferroelectric film as a capacitor which accumulates and stores electric charge. If an electric field is applied to a ferroelectric film, the magnitude and direction of the polarization (spontaneous polarization) formed in the ferroelectric film can be controlled. Polarization in a ferroelectric material is accompanied by hysteresis, and so the response of this polarization to an electric field, and the capacity to retain this response, can be utilized as a memory function. That is, ferroelectric memory utilizes functions for polarization reversal and maintenance to enable high-speed operation at low voltages and with low power consumption.

Compared with EPROMs (erasable programmable read-only memory), flash memory, and other types of nonvolatile memory, ferroelectric memory is superior with respect to write speed and low operating voltage. This is because the polarization reversal time in a ferroelectric film is on the order of several nanoseconds, and because the voltage required for polarization reversal can be held to approximately 2.0 V through optimization of the ferroelectric film fabrication method. In addition, the data in ferroelectric memory can be overwritten more than 10¹² times; consequently, ferroelectric memory is currently being utilized as RAM.

However, in conventional processes to fabricate ferroelectric memory, writing of initial data into the ferroelectric memory is performed before mounting of headers or the molding process for each chip. Here a chip is a unit of configuration of a structure in which the ferroelectric material is enclosed between electrodes; such a structure is called a single chip (and hereafter may also be called a “ferroelectric chip” or simply a “chip”). That is, the initial data writing is performed in the state in which a plurality of chips on a wafer are formed integrally. After the initial data writing in the ferroelectric memory, the individual ferroelectric memory chips are cut away from the wafer, and mounting on a header or a molding assembly process is performed. In these ferroelectric memory chip assembly processes, heat treatment of the ferroelectric memory is included. When a ferroelectric memory chip is heat-treated in an assembly process or similar, the hysteresis curve of the ferroelectric film of the ferroelectric memory is known to be imprinted (also called “shifting”) according to the remanent polarization state prior to the heat treatment, that is, according to the data held at that time.

After writing data to the ferroelectric memory, if the memory is stored (left standing) for a long period of time, when an attempt is made to overwrite the stored data, the overwriting becomes difficult. This phenomenon is also caused by imprinting of the hysteresis curve on the ferroelectric material.

It may not be possible to write new data reliably to ferroelectric memory in which a hysteresis curve has been imprinted, such as well-known 2T2C-type ferroelectric memory of the prior art, configured using two transistors (2T) and two capacitors (2C). For example, prior to the chip assembly process, suppose that initial data had been written to each of a pair of memory cell capacitors in ferroelectric memory. When data in the state opposite the initial data state (the reversed state) is written to the memory cell capacitors after chip assembly, because of the imprinting, the difference in charge amounts between the two capacitors at the time of writing is smaller than if there had been no imprinting, and so new data cannot be written reliably.

Hence in the prior art, degradation of the characteristics as RAM was avoided by suppressing the occurrence of imprinting, which detracts from the reliability of ferroelectric memory used as RAM.

After conducting studies, the inventors of this invention arrived at the following recognition. If writing of initial data is performed after the chip assembly process, rather than before the chip assembly process, initial data writing can be performed in a state in which no data has been written (a state in which no remanent polarization occurs), so that the problem of the occurrence of imprinting can be avoided.

In addition, after initial data writing, by taking advantage of the occurrence of imprinting due to heating, ferroelectric memory can be converted into ROM, and by again heat-treating ferroelectric memory converted into ROM, conversion into RAM is possible.

### SUMMARY OF THE INVENTION

The method of manufacture of ferroelectric memory of this invention has the following features with respect to configuration.

The process of manufacture of a ROM, using ferroelectric memory comprising a ferroelectric film, comprises a chip assembly process in which the chip is assembled; a data writing process in which data is written to the ferroelectric memory following the chip assembly process; and a first heat treatment process in which, after the data writing process, the ferroelectric film is heat-treated at a heat treatment temperature T1 (° C.) which is lower than the phase transition temperature T_{c} (° C.) of the ferroelectric film.

By adopting these processes, ferroelectric memory can be fabricated in which the remanent polarization state corresponding to data written in the data writing process is stabilized through the first process for heat treatment of the ferroelectric film.

As a result, the polarization state in the fabricated ferroelectric memory reversed from (opposite of) the stable polarization state becomes an unstable state, and it becomes difficult to write data opposite the data written in the data writing process. As a result, the ferroelectric memory has substantially similar functions as read-only memory (ROM). In other words, the ferroelectric memory can be made to operate as ROM. Hereafter, “effectively becomes an element having functions equivalent to those of ROM” will be abbreviated to “effectively convert into ROM”.

Hence ferroelectric memory which has been effectively converted into ROM through a first heat treatment can be utilized as ROM.

Further, the ferroelectric memory manufacturing processes of this invention also comprise a second heat treatment process, in which the ferroelectric film of ferroelectric memory which has been converted into ROM is heat-treated at a heat treatment temperature T2 (° C.) higher than the phase transition temperature T_{c} (° C.) of the ferroelectric film.

Through the inclusion of this second heat treatment process, by means of a second heat treatment process of the ferroelectric film of ferroelectric memory which has effectively been converted into ROM, the imprinted state formed by the first heat treatment process can be returned once again to the state previous to the imprinting. That is, ferroelectric memory can be fabricated such that ferroelectric memory which has once been formed so as to operation as ROM can again be made to function as random-access memory (RAM).

Thus in this invention, while ferroelectric memory which can function as conventional RAM is converted into ROM by means of a first heat treatment process, ferroelectric memory which has been converted into ROM can again be made to function as RAM by means of a second heat treatment process.

As a result, ferroelectric memory can be used selectively as ROM or as RAM in exactly the same usage environment, so that the advantages of use of ferroelectric memory can be further enhanced.

And, because conversion into (usage as) ROM or RAM is possible through such heat treatment processes, manufacturing costs can be reduced compared with the prior art, which required separate complicated manufacturing processes to manufacture ROM and RAM.

### BRIEF DESCRIPTION OF THE DRAWINGS

The foregoing and other objects, features and advantages of the present invention will be better understood from the following description taken in connection with the accompanying drawings, in which:

FIG. 1 is a flowchart which explains the method of manufacture of ROM and RAM of this invention;

FIG. 2 is a drawing showing schematically the circuit configuration of ferroelectric memory;

FIG. 3 is a (first) hysteresis characteristic diagram, used to explain an embodiment of this invention;

FIG. 4 is a drawing used to explain an embodiment of this invention;

FIG. 5 is a (second) hysteresis characteristic diagram, used to explain an embodiment of this invention; and,

FIG. 6 is a (third) hysteresis characteristic diagram, used to explain an embodiment of this invention.

### DESCRIPTION OF THE PREFERRED EMBODIMENTS

Below, an embodiment of this invention is explained, referring to the drawings.

The embodiment explained below is no more than a preferred example of the invention, and so does not in any way limit the invention to this preferred example; nor are any limits imposed by numerical conditions used in the description below.

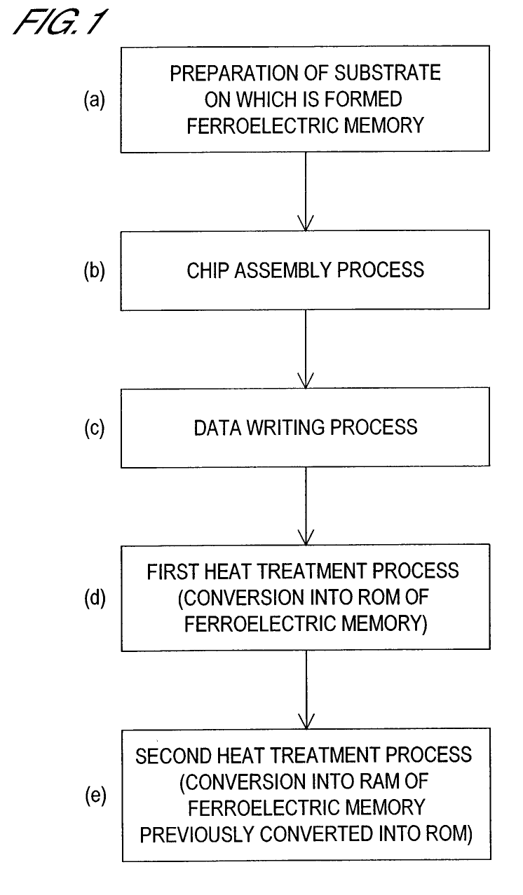

A method of manufacture of the ROM and RAM of this invention is explained below, referring to the manufacturing process drawing (flowchart) shown in FIG. 1.

A ROM manufacturing method of this invention comprises a chip assembly process, a data writing process, and a first heat treatment process.

First, in the chip assembly process, after preparing a substrate on which is formed a ferroelectric memory ((a) in FIG. 1), chip assembly using this substrate is performed ((b) in FIG. 1).

In this embodiment, SrBi₂Ta₂O₉ (SBT) is used as the ferroelectric film of the ferroelectric capacitors comprised by the ferroelectric memory; but in place of this SBT, PbZrTiO₃ film, Pb₅Ge₃O₁₁ film, Bi₄Ti₃O₁₂ film, or similar can be used.

The chip assembly process ((b) in FIG. 1) is a process in which a plurality of chips formed integrally on one wafer are cut away from the wafer as separate chips, and each chip is mounted in a package. This chip assembly process includes normal processes for connection to headers, for molding and other assembly, and other processes in which heat treatment of the chip into which ferroelectric memory is being incorporated is performed.

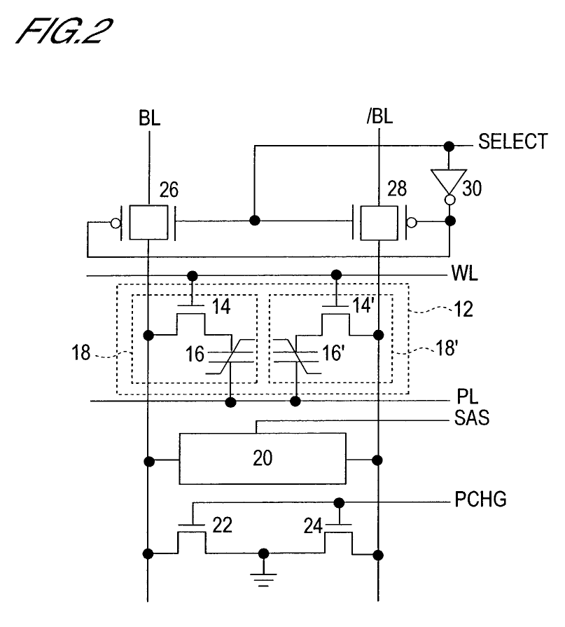

FIG. 2 shows one example of the configuration of a circuit comprising ferroelectric memory obtained through this chip assembly process. In the example shown in FIG. 2, the ferroelectric memory is the (complementary) two-transistor, two-capacitor (2T2C) type memory. Normally ferroelectric memory comprises a plurality of memory cells, but here only a single 2T2C-type memory cell is shown.

As shown in FIG. 2, this ferroelectric memory cell 12 has a main cell 18 comprising a (MOS) transistor 14 and ferroelectric capacitor 16, and a dummy cell 18′ comprising a (MOS) transistor 14′ and ferroelectric capacitor 16′.

The capacitor 16 is connected to the bit line BL via the transistor 14, and the capacitor 16′ is connected to the bit line /BL via the transistor 14′. The bit lines BL and /BL are a bit line pair; these bit lines are connected to the latch-type sense amplifier 20. The sense amplifier 20 is connected to the sense amplifier control signal line SAS.

On the other hand, the word line WL is provided orthogonally to the bit lines BL and /BL, and memory cells (18, 18′) are connected at these intersection points.

Each of the gate electrodes of the above-mentioned transistors (14, 14′) is connected to the word line WL, the drain electrode of the transistor 14 is connected to the bit line BL, and the drain electrode of the transistor 14′ is connected to the bit line /BL. The source electrode of the transistor 14 is connected to one of the electrodes of the ferroelectric capacitor 16, and the source electrode of the transistor 14′ is connected to one of the electrodes of the ferroelectric capacitor 16′.

The electrode of each of the ferroelectric capacitors (16, 16′) not connected to a source electrode is connected to the plate line PL.

The bit line BL is connected to ground voltage via a (MOS) transistor 22, the gate electrode of which is connected to the bit line precharge control signal line PCHG; the bit line /BL is connected to ground voltage via a (MOS) transistor 24, the gate electrode of which is connected to the same bit line precharge control signal line PCHG.

A transmission gate (TM gate) 26 is inserted into the bit line BL, and a transmission gate (TM gate) 28 is inserted into the bit line /BL. Each of the gate electrodes of these TM gates 26, 28 is connected to the bit line selection line SELECT; however, one of the gate electrodes of the TM gates (26, 28) is connected to the bit line selection line SELECT via a NOT gate 30. Here the input terminal of the NOT gate 30 is connected to the side of the bit line selection line SELECT.

Just after chip assembly, the ferroelectric memory functions as random-access memory, that is, is in the RAM state. Hence operations to write data to and read data from this ferroelectric memory in the RAM state are performed using normal procedures.

In other words, in 2T2C-type ferroelectric memory in the RAM state, opposite logical level voltages (“H” and “L”) are written to the two ferroelectric capacitors (16, 16′), and the sense amplifier 20 amplifies the voltage difference read between the two ferroelectric capacitors (16, 16′) to perform a data read operation.

Next, data writing of this ferroelectric memory is performed in order to cause ferroelectric memory in the above-described RAM state to function as a read-only memory, that is, to perform conversion into ROM ((c) in FIG. 1).

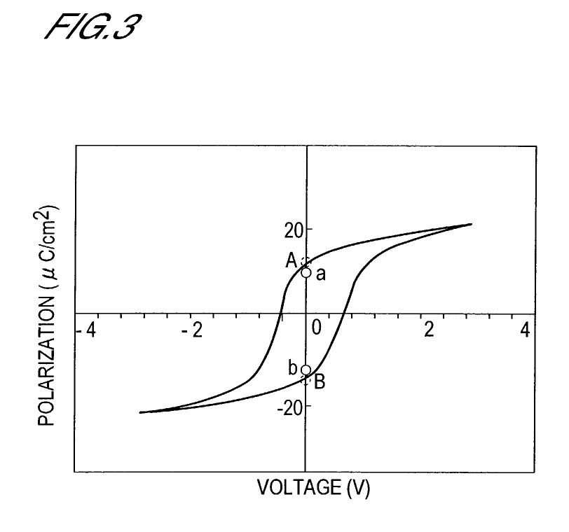

First, the anticipated hysteresis characteristics (ferroelectric capacitor characteristics) of the ferroelectric capacitor 16, for which data has never yet been written to the memory cell 12 following the above-described chip assembly process, are explained, referring to FIG. 3.

FIG. 3 shows the hysteresis characteristic anticipated for the ferroelectric capacitor 16. In this figure, the horizontal axis indicates the voltage (V) applied to the capacitor, and the vertical axis indicates the polarization per unit area (μC/cm²).

The points a and b in the figure indicate measured values of the remanent polarization when this hysteresis curve was obtained; these values are substantially the same as the remanent polarization values (at points A and B) obtained theoretically from the intersections of the Y-axis with the hysteresis curve, but here the points a and b are used in the explanation.

Because the hysteresis shape has good symmetry about the origin (zero), it is seen that a stable state is obtained whether the polarization state is at point a or at point b.

Ferroelectric memory with the voltage applied to a ferroelectric capacitor set to 0 V (power supply turned off) is memory in which the remanent polarization remaining in the ferroelectric capacitor is used as nonvolatile data.

Hence the ferroelectric memory at this time has good data retaining characteristics even when either of the logical voltage levels (“H” or “L”) is applied (data is written) to the ferroelectric capacitor 16; that is, a “RAM state” is formed.

Initial data writing is then performed for ferroelectric memory in this RAM state.

Specifically, in this embodiment, for example, the logical value “1” is written to the memory cell 12. At this time, the remanent polarization (retained data) obtained by applying the logical voltage “H” to the ferroelectric capacitor 16 is the point a. Conversely, if the logical value “0” is written to the memory cell 12, the remanent polarization of the ferroelectric capacitor 16 is at the inverted position, point b (see FIG. 3).

1. Conversion into ROM of Ferroelectric Memory (RAM)

Next, a first heat treatment process is performed on ferroelectric memory which is in the RAM state, with the writing process completed ((d) in FIG. 1). In this first heat treatment process, the ferroelectric film comprised by the ferroelectric memory is heat-treated at a heating temperature below the phase transition temperature of the ferroelectric film.

Specifically, ferroelectric memory which can operate in a “RAM state” is placed in an electric furnace (in an air atmosphere), and baking is performed at a heat treatment temperature T1 below the phase transition temperature T_{c} (° C.) of the ferroelectric film.

The phase transition temperature T_{c} (° C.) of the SrBi₂Ta₂O₉ (SBT) of the ferroelectric film used in this embodiment is approximately 350° C.; hence baking is performed for one hour at a heat treatment temperature T1 (° C.) below this T_{c} (° C.), such as for example 220° C.

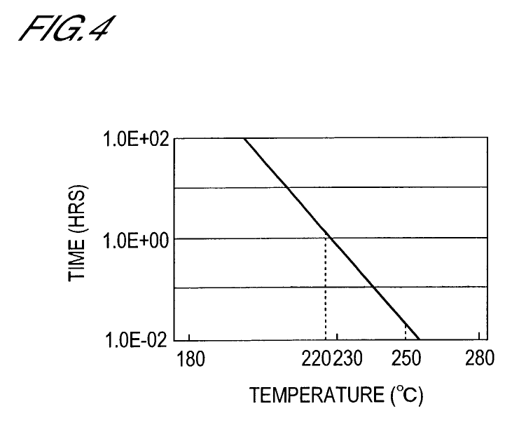

FIG. 4 is a characteristic diagram showing the relation between heat treatment temperature T1 (° C.) and heating time for SrBi₂Ta₂O₉ (SBT). In FIG. 4, the temperature is plotted along the horizontal axis, and the time (in hours) is plotted along the vertical axis. As is clear from FIG. 4, the relation between heating time T1 (° C.) and heating time for SBT is a linear relation, and so it is preferable that a combination of temperature and heating time on this straight line be chosen. However, from the standpoint of alleviating process complications due to characteristic degradation of the ferroelectric film and to longer heating times, it is preferable that the heating temperature T1 (° C.) be in the range 220° C. to 250° C., that is, in the range 100° C. to 130° C. below the SBT phase transition temperature T_{c} (° C.). In particular, in the case of ferroelectric memory using SBT as the ferroelectric film, by subjecting the ferroelectric memory after data writing to heat treatment at a heat treatment temperature T1 (° C.) of approximately 220° C. for about one hour, the imprinting occurring in the ferroelectric memory can be controlled more precisely than when subjecting the ferroelectric memory to heat treatment at higher temperatures for shorter lengths of time.

Even when using ferroelectric film other than SBT, appropriate values of the heat treatment temperature T1 (° C.) and heating time can be chosen arbitrarily; however, it is preferable that the heat treatment temperature T1 (° C.) of a given ferroelectric film be at a temperature lower by a range between 50° C. and 150° C. than the phase transition temperature T_{c} (° C.) for that ferroelectric film.

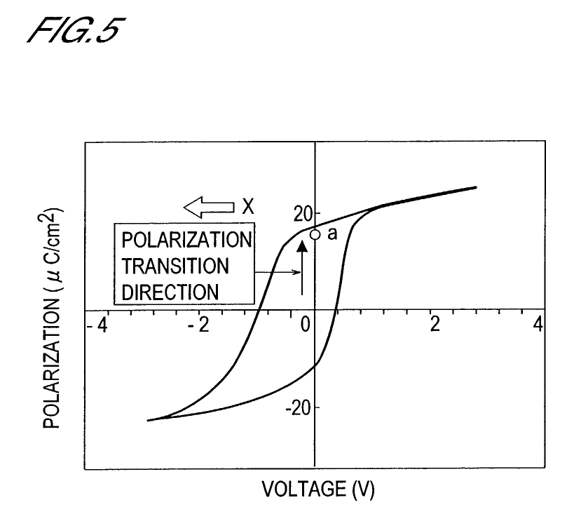

FIG. 5 shows the hysteresis characteristic of a ferroelectric capacitor 16 for which baking has been performed in the above-described first heat treatment process. In the figure, the horizontal axis shows the voltage (V), and the vertical axis shows the polarization per unit area (μC/cm²).

From the hysteresis characteristic shown in FIG. 5, it can be seen that by means of this baking, the hysteresis curve shape of the ferroelectric capacitor 16 prior to baking (see FIG. 3) has been imprinted (shifted) depending on the remanent polarization prior to the making.

As was explained referring to FIG. 3, as a result of baking, the hysteresis curve of the ferroelectric capacitor 16 is imprinted in the leftward direction (the direction of the arrow X), as a result of the fact that the remanent polarization prior to the baking was at point a.

This occurs because during baking or when the film is otherwise left at a high temperature, electric charge existing within the ferroelectric capacitor with remanent polarization at point a is gradually redistributed in a direction which stabilizes the polarization state, that is, in the direction of positive (+) polarization values, to generate an electric field (internal electric field).

Through this imprinting, the data retention characteristic of the polarization state (point a) prior to imprinting is improved, while the data retention characteristic of the polarization state reversed from this polarization state (point b) (see FIG. 3) is worsened.

As a result, the polarization state prior to imprinting (point a) becomes a state in which reversal of the polarization state by the internal electric field is difficult, that is, a stable state; and on the other hand, even if an attempt is made to write data opposite the data corresponding to the polarization state before imprinting (point a), a state is entered in which the polarization state corresponding to the opposite data (point b) cannot easily be maintained due to the internal electric field, that is, the state is unstable.

Hence even if an attempt is made to write data opposite the data that had been written prior to baking of the ferroelectric memory, because the reversed polarization is an unstable state, the polarization state immediately makes a transition to the polarization state which is the stable state, and so an effective “ROM state (ROM conversion)”, in which writing of the opposite data is difficult, results.

In this way, ferroelectric memory (originally RAM) in which imprinting has occurred due to baking can be utilized as ROM. As already explained, operations to read data in ferroelectric memory in this “ROM state” can be performed by the normal procedure used to read data in ferroelectric memory (RAM).

2. Conversion into RAM of ROM-Converted Ferroelectric Memory

Next, a second heat treatment process is performed on the “ferroelectric memory converted into ROM” obtained by the above-described processes ((e) in FIG. 1). In this second heat treatment process, ferroelectric film comprised by ferroelectric memory is heat-treated at a heat treatment temperature above the phase transition temperature of the ferroelectric film.

Specifically, ferroelectric memory in the “ROM state” is placed in an electric furnace, and baking is performed at a heat treatment temperature T2 (° C.) equal to or above the phase transition temperature T_{c} (° C.) of the ferroelectric film.

It is thought that a phase transition occurs when the ferroelectric film reaches the phase transition temperature T_{c} (° C.), so that in the second heat treatment process, it is sufficient to set the heat treatment temperature T2 (° C.) so as to exceed the phase transition temperature T_{c} (° C.) for the ferroelectric film (in this case, SBT). This includes cases in which only a few seconds of heating time are sufficient. Due to considerations of the possibility of degradation of the ferroelectric film characteristics, it is preferable that the heat treatment temperature T2 (° C.) be set to approximately the phase transition temperature T_{c} (° C.).

Because the ferroelectric film used in this embodiment is SBT (phase transition temperature T_{c} (° C.)=350° C.), baking is performed for one minute at a heat treatment temperature T2 (° C.) of 350° C.

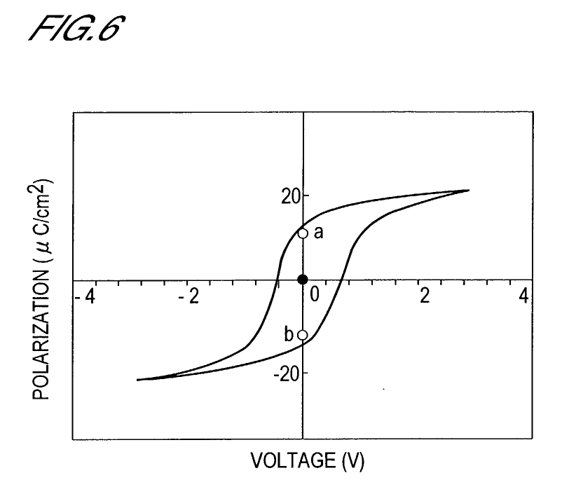

FIG. 6 shows the hysteresis characteristic of a ferroelectric capacitor 16 for which the above baking has been performed. In this figure, the horizontal axis indicates the voltage (V), and the vertical axis indicates the polarization per unit area (μC/cm²).

As shown in FIG. 6, by means of this baking, the remanent polarization of the imprinted hysteresis characteristic (see FIG. 4) becomes zero (equivalent to the black circle in the figure), and the imprinting vanishes. Even in a rising-temperature process after baking, the remanent polarization of the ferroelectric film remains zero.

At this time, because the remanent polarization of the ferroelectric capacitor 16 is zero, either of the logical voltages (“H” or “L”) can immediately be applied (data can be written) to the ferroelectric capacitor 16.

Hence similarly to the explanation of FIG. 3, a “RAM state (RAM conversion)” is entered, in which the remanent polarization can become either point a or point b in the figure.

In this way, by performing baking on the ferroelectric film of ferroelectric memory which has effectively been converted into ROM, conversion once again into ferroelectric memory having functions as RAM is possible.

As is clear from the above explanation, in this embodiment, ferroelectric memory which originally functions as RAM can be converted into ROM by means of a first heat treatment process; and moreover, ferroelectric memory which has been converted into ROM can again be converted into RAM by means of a second heat treatment process.

Hence compared with the prior art, in which separate complicated manufacturing processes were necessary for the manufacture of ROM and RAM, the ability to convert between (use as) ROM and RAM through heat treatment can be utilized to reduce manufacturing costs.

Moreover, ferroelectric memory can be used selectively as ROM or as RAM in an identical usage environment, so that ferroelectric memory can be used over a broad range of applications, according to the purpose and design.

This invention is in no way limited to the conditions of this embodiment or to the above-described combinations. Thus the present invention can be applied by appropriate combination of conditions in appropriate arbitrary stages.

For example, in the above-described embodiment, the case in which the memory cell configuration is a 2T2C-type ferroelectric memory was explained; but the present invention is not thereby limited. Hence this invention can be applied appropriately even to ferroelectric memory with a 1T1C or other memory cell configuration, and similar advantageous results can be anticipated.

As is clear from the above explanation, by means of this invention, ferroelectric memory which originally is used as RAM can be converted into (used as) ROM through a first heat treatment process, and ferroelectric memory which functions as ROM can again be converted into (used as) RAM through a second heat treatment process.

Hence compared with the prior art, in which fabrication using separate manufacturing processes was necessary for the manufacture of ROM and RAM, manufacturing costs can be decreased, and moreover ferroelectric memory can be used selectively as ROM or as RAM in the same usage environment, so that ferroelectric memory can be used over a broad range of applications, according to the purpose and design.

What is claimed is:

1. A method of manufacture of ferroelectric memory comprising a ferroelectric film, said method comprising:
assembling a chip of said ferroelectric memory;
writing data to said ferroelectric memory, after the chip assembly process; and,
subjecting said ferroelectric memory, after the data writing process, to heat treatment at a heat treatment temperature T1 (° C.) below the phase transition temperature T_{c} (° C.) of the ferroelectric film, causing imprinting in said ferroelectric film.

2. The method of manufacture of ferroelectric memory according to claim 1, wherein subjecting said ferroelectric memory to heat treatment is performed at said heat treatment temperature T1 (° C.) such that (T_{c}−150) (° C.)≦T1 (° C.)≦(T_{c}−50) (° C.) is satisfied.

3. The method of manufacture of ferroelectric memory according to claim 1, wherein said ferroelectric film is an SrBi₂Ta₂O₉ film and subjecting said ferroelectric memory to heat treatment is performed substantially for one hour, and said heat treatment temperature T1 (° C.) is substantially 220° C.

4. The method of manufacture of ferroelectric memory according to claim 1, wherein read-only memory is manufactured as said ferroelectric memory.

5. The method of manufacture of ferroelectric memory according to claim 1, wherein heat treatment of said ferroelectric memory is performed in said chip assembly process.

6. The method of manufacture of ferroelectric memory according to claim 1, wherein subjecting said ferroelectric film to heat treatment is performed at a heat treatment temperature t1 (° C.) for stabilizing the polarization state of said ferroelectric film in the polarization direction corresponding to said data.

7. A method of manufacture of ferroelectric memory comprising:
assembling a chip of said ferroelectric memory which has a ferroelectric film;
writing data to said ferroelectric memory, after the chip assembly process;
providing a read-only memory through subjecting said ferroelectric memory, after the data writing process, to a first heat treatment at a heat treatment temperature T1 (° C.) below the phase transition temperature T_{c} (° C.) of the ferroelectric film; and
selecting said ferroelectric film comprised by said read-only memory, after the first treatment process, to a second heat treatment at a heat treatment temperature T2 (° C.) equal to or higher than the phase transition temperature T_{c} (° C.) of the ferroelectric film.

8. The method of manufacture of ferroelectric memory according to claim 7, wherein subjecting said ferroelectric memory to heat treatment is performed at said heat treatment temperature T1 (° C.) such that (T_{c}−150) (° C.)≦T1 (° C.)≦(T_{c}−50)(° C.) is satisfied.

9. The method of manufacture of ferroelectric memory according to claim 7, wherein said ferroelectric film is an SrBi₂Ta₂O₉ film, said first heat treatment process is performed substantially for one hour and said heat treatment temperature T1 (° C.) is substantially 220° C., and said second heat treatment process is performed at said heat treatment temperature T2 (° C.) of substantially 350° C. or higher.

10. The method of manufacture of ferroelectric memory according to claim 7, wherein random-access memory is manufactured as said ferroelectric memory after said second heat treatment process.

11. The method of manufacture of ferroelectric memory according to claim 7, wherein said ferroelectric memory is subjected to heat treatment in said chip assembly process.

12. The method of manufacture of ferroelectric memory according to claim 7, wherein said second heat treatment temperature T2 (° C.) is approximately the phase transition temperature T_{c} (° C.) of said ferroelectric film.

13. The method of manufacture of ferroelectric memory according to claim 7, wherein said second heat treatment process causes the remanent polarization of said ferroelectric film to be zero.
